(19) United States
(12) Patent Application Publication
(10) Pub. No.: US 2021/0383843 A1
(43) Pub. Date: Dec. 9, 2021

(54) METHOD FOR FORMING A MEMORY AND MEMORY

(71) Applicant: CHANGXIN MEMORY TECHNOLOGIES, INC., Hefei City (CN)

(72) Inventor: Zhe ZHAO, Hefei City (CN)

(21) Appl. No.: 17/412,692

(22) Filed: Aug. 26, 2021

Related U.S. Application Data
(63) Continuation of application No. PCT/CN2021/083067, filed on Mar. 25, 2021.

(30) Foreign Application Priority Data
Apr. 23, 2020 (CN) 202010326652.X

(51) Int. Cl. G11C 5/06; H01L 27/108

(52) U.S. Cl. CPC G11C 5/063; H01L 27/10885; H01L 27/10897; H01L 27/10805; H01L 27/1085

(57) ABSTRACT

An embodiment of the present application provides a method for forming a memory and the memory. The formation method includes: providing a substrate, the substrate including an array region and a peripheral region, the array region having thereon a plurality of discrete bitline structures, and an isolation layer being formed on a side wall of the bitline structure; forming a first dielectric layer at the array region and the peripheral region; patterning the first dielectric layer located at the array region to form an opening, and etching part of the isolation layer during a process of etching away the first dielectric layer, a remaining part of the isolation layer having a gap; and forming a second dielectric film located on a top surface of the isolation layer and the bitline structure.

### CROSS-REFERENCE TO RELATED APPLICATIONS

This application is a continuation application of International Patent Application No. PCT/CN2021/083067, filed on Mar. 25, 2021, which claims priority to Chinese Patent Application No. 202010326652.X, filed with the Chinese Patent Office on Apr. 23, 2020 and entitled “METHOD FOR FORMING A MEMORY AND MEMORY.” International Patent Application No. PCT/CN2021/083067 and Chinese Patent Application No. 202010326652.X are incorporated herein by reference in their entireties.

### TECHNICAL FIELD

The present application relates to the field of semiconductors, in particular to a method for forming a memory and the memory.

### BACKGROUND

With improvements of manufacture procedure, DRAM (Dynamic Random Access Memory) has an increased level of integration, further reduced feature size and line width, and an increasingly decreased spacing between adjacent bitline structures. However, the decreased spacing between adjacent bitline structures would lead to an increased depth-to-width ratio of an opening between the adjacent bitline structures, which affects a saturation current of a DRAM array region, thereby influencing a running efficiency of the DRAM.

In the case where the line width of the DRAM is reduced increasingly, how to increase the saturation current of the DRAM array region is an urgent problem to be solved currently.

### SUMMARY

An embodiment of the present application provides a method for forming a memory and the memory, which can reduce a parasitic capacitance of a DRAM array region, and decrease a resistance of a subsequently formed capacitor contact window by increasing a contact area of a capacitor contact hole, thereby increasing the saturation current of the DRAM array region.

In order to solve the above technical problem, an embodiment of the present application provides a method for forming a memory, including: providing a substrate, the substrate including an array region and a peripheral region, the array region having thereon a plurality of discrete bitline structures, and the bitline structure being provided with an isolation layer being on a side wall; forming a first dielectric layer which covers the bitline structure at the array region and the peripheral region; patterning and etching the first dielectric layer located at the array region to form an opening, and etching part of the isolation layer during a process of etching away the first dielectric layer, a remaining part of the isolation layer having a gap; forming a second dielectric film located on a top surface of the isolation layer and the bitline structure, the second dielectric film being also located on a side wall of the isolation layer and the substrate between the bitline structure; by a first etching process, etching the second dielectric film on the side wall of the isolation layer to form a second dielectric layer; and by a second etching process, etching part of the substrate at a bottom of the opening to form a capacitor contact hole.

Since a spacing between adjacent bitline structures becomes less, a depth-to-width ratio of an opening between the adjacent bitline structures would increase, which affects a saturation current of a DRAM array region, thereby influencing a running efficiency of the DRAM. In the present application, a parasitic capacitance of the DRAM array region is reduced by forming an isolation structure, which leads to a gap formed between the top of the isolation layer and the bitline structure in the subsequent process, and an isolation effect of the isolation structure is guaranteed by forming the second dielectric layer to fill a gap or sealing the isolation layer; and with the first etching process and the second etching process, the second dielectric layer on the side wall of the isolation layer and the substrate at the bottom of part of the opening are etched, which increases a contact area of a capacitor contact hole, thereby reducing a resistance of a subsequently formed capacitor contact window and increasing the saturation current of the DRAM array region.

Additionally, the forming a second dielectric film located on a top surface of the isolation layer and the bitline structure includes: forming the second dielectric film for filling the gap, the second dielectric film being also located on the top surface of the isolation layer and the bitline structure. The parasitic capacitance of the DRAM array region is reduced by forming a NON-laminated isolation structure.

Additionally, the forming a second dielectric film located on a top surface of the isolation layer and the bitline structure includes: forming the second dielectric film for sealing the gap, the second dielectric film being partially located on top of the gap, the second dielectric film being also located on a top surface of the isolation layer and the bitline structure. The parasitic capacitance of the DRAM array region is reduced by forming an air gap isolation structure. In addition, after the forming a second dielectric film located on a top surface of the isolation layer and the bitline structure and before the etching the second dielectric film on the side wall of the isolation layer by the first etching process, the method includes: etching away the second dielectric film on the top surface of the isolation layer and the bitline structure and on the substrate between the bitline structures.

Additionally, the second dielectric layer is made of the same material as the first dielectric layer.

Additionally, the etching the first dielectric layer located at the array region to form an opening includes: etching away the first dielectric layer located at the array region until a top surface of the bitline structure is exposed; and etching away the first dielectric layer located between the bitline structures to form the opening.

Additionally, an etching material for etching away the first dielectric layer includes hydrofluoric acid.

Additionally, the isolation layer includes a first isolation layer, a second isolation layer and a third isolation layer; the first isolation layer is located on the side wall of the bitline structure; the second isolation layer is located on a side wall of the first isolation layer away from the bitline structure; the third isolation layer is located on a side wall of the second isolation layer away from the first isolation layer; and the etching part of the isolation layer during a process of etching away the first dielectric layer includes: etching part of the second isolation layer with a certain thickness.

Additionally, the forming a first dielectric layer which covers the bitline structure at the array region and the peripheral region includes: forming a first dielectric film for filling a gap between the bitline structures at the array region and the peripheral region, the first dielectric film covering a top surface of the bitline structure; and planarizing a top surface of the first dielectric film to form the first dielectric layer.

Additionally, the first dielectric film is formed using a spin coating process.

The embodiment of the present application further provides a memory, including: a substrate, the substrate including an array region and a peripheral region, the array region having thereon a plurality of discrete bitline structures; an isolation layer located on a side wall of the bitline structure, the isolation layer having a gap between the isolation layer; a first dielectric layer which covers the peripheral region and a second dielectric layer located in the gap for forming an isolation structure; and a capacitor contact hole on the substrate between the bitline structures.

Additionally, the second dielectric layer is configured to fill the gap to form the isolation structure, or the second dielectric layer is configured to seal the gap to form the isolation structure.

Additionally, the isolation layer includes a first isolation layer, a second isolation layer and a third isolation layer; the first isolation layer is located on the side wall of the bitline structure; the second isolation layer is located on a side wall of the first isolation layer away from the bitline structure; the third isolation layer is located on a side wall of the second isolation layer away from the first isolation layer.

Compared with a related art, in the present application, the parasitic capacitance of the bitline structure is reduced by the isolation structure, a contact area between the subsequently formed capacitor contact window and the substrate is increased and the resistance of the subsequently formed capacitor contact window is decreased through the capacitor contact hole formed by etching on the substrate between the bitline structures, thereby increasing the saturation current of the DRAM array region.

### BRIEF DESCRIPTION OF DRAWINGS

FIGS. 1 to 12 are schematic structural diagrams corresponding to steps of a method for forming a memory according to an embodiment of the present application; and

FIGS. 13 to 16 are schematic structural diagrams corresponding to steps of a method for forming a memory according to another embodiment of the present application.

### DESCRIPTION OF EMBODIMENTS

At present, in the case where the line width of the DRAM is reduced increasingly, the saturation current of the DRAM array region would be decreased gradually. Therefore, how to increase the saturation current of the DRAM array region is an urgent problem to be solved currently.

In order to solve the above technical problem, an embodiment of the present application provides a method for forming a memory, including: providing a substrate, the substrate including an array region and a peripheral region, the array region having thereon a plurality of discrete bitline structures, and an isolation layer being formed on a side wall of the bitline structure; forming a first dielectric layer which covers the bitline structure at the array region and the peripheral region; patterning and etching the first dielectric layer located at the array region to form an opening, and etching part of the isolation layer during the process of etching away the first dielectric layer, a remaining part of the isolation layer having a gap; forming a second dielectric film located on a top surface of the isolation layer and the bitline structure, the second dielectric film being also located on the substrate between the side wall of the isolation layer and the bitline structure; by a first etching process, etching the second dielectric film on the side wall of the isolation layer to form a second dielectric layer; and by a second etching process, etching part of the substrate at the bottom of the opening to form a capacitor contact hole.

In order to make the objectives, the technical solutions, and the advantages of the embodiments of the present application more clear, the detailed description of the embodiments of the present application is given below in combination with the accompanying drawings. Those ordinary skill in the art can understand that many technical details are provided in the embodiments of the present application so as to make the readers better understand the present application. However, even if these technical details are not provided and based on a variety of variations and modifications of the following embodiments, the technical solutions sought for protection in the present application can also be realized. The following embodiments are divided for convenience of description, and should not constitute any limitation to the implementation of the present application. The embodiments may be combined with each other and referred to each other without contradiction.

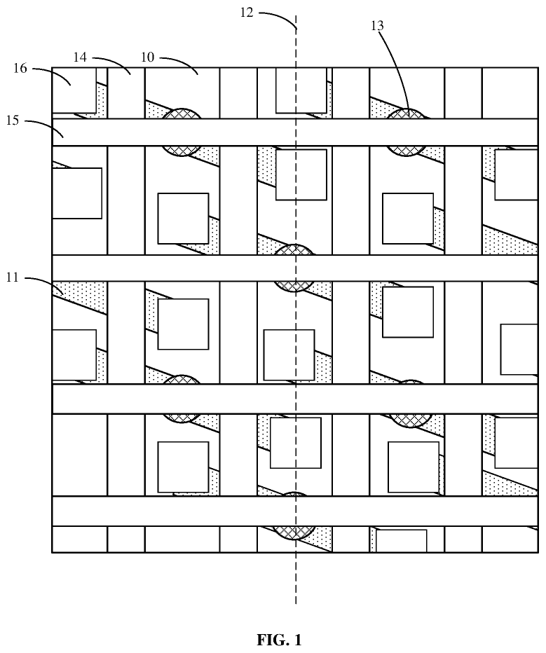

FIGS. 1 to 12 are schematic structural diagrams corresponding to steps of a method for forming a memory according to the present embodiment, and the method for forming a memory in the present embodiment will be specifically described below in combination with the drawings.

Referring to FIGS. 1 to 7, FIG. 1 is a schematic top view of a provided substrate and a capacitor contact window formed subsequently, and FIG. 2 is a schematic sectional view of a memory in a direction of a dashed line 12 in FIG. 1.

Referring to FIG. 1, a substrate 10 includes an active region 11, a bitline contact window 13, a wordline 14, a bitline structure 15 and a capacitor contact 16, illustrating a schematic sectional view of a method for forming a memory denoted by a dashed line 12 in the subsequent memory formation method. It should be noted that in the present embodiment, the method for forming a DRAM array region is mainly introduced, and for the sake of those skilled in the art to under the implementation of this solution, the corresponding drawings only show a structural change in the DRAM array region.

The substrate 10 is provided, including an array region and a peripheral region, the array region having thereon a plurality of discrete bitline structures 15, and an isolation layer being formed on a sidewall of the bitline structure 15.

Referring to FIG. 2, the substrate 10 includes buried wordlines, shallow trench isolation layers, active regions, or the like. The bitline structure 15 includes a bitline contact layer 101, a bottom dielectric layer 102, a metal layer 103, and a top dielectric layer 104. Specifically, the bitline contact layer 101 includes the bitline contact window 13, and only one of three consecutive bitline structures 15 is connected to the active region in the substrate 10 through the bitline contact window 13 in the sectional direction of the dashed line 12 in FIG. 1. The present embodiment is exemplified by a middle bitline structure 15 connected to the active region in the substrate 10 through the bitline contact window 13.

A material of the bitline contact window 13 includes tungsten or polysilicon, materials of the bottom dielectric layer 102 and the top dielectric layer 104 include silicon nitride, silicon dioxide or silicon oxynitride, and the metal layer 103 is made of a conductive material or a plurality of conductive materials, such as doped polysilicon, titanium, titanium nitride, tungsten, tungsten compounds, or the like.

The isolation layer includes a first isolation layer, a second isolation layer and a third isolation layer; the first isolation layer is located on aside wall of the bitline structure 15; the second isolation layer is located on the sidewall of the first isolation layer away from the bitline structure 15; the third isolation layer is located on the sidewall of the second isolation layer away from the first isolation layer, and the formation steps of the isolation layer will be described in detail below with reference to the accompanying drawings.

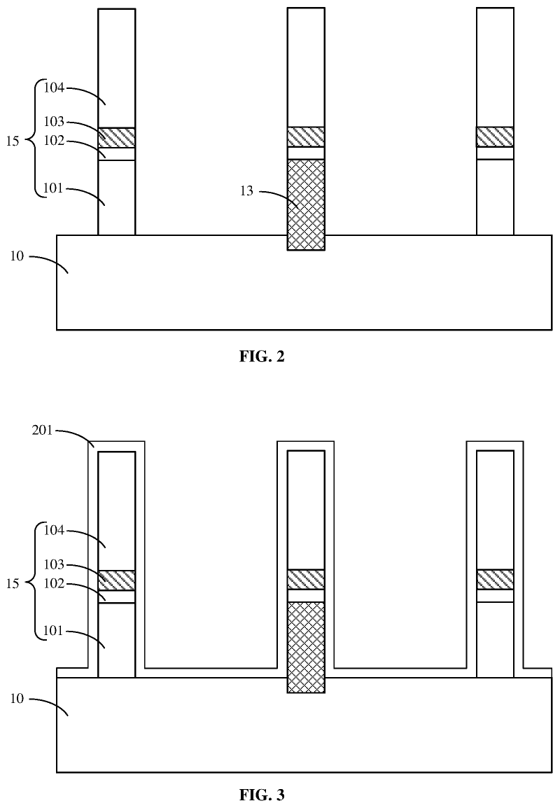

Referring to FIG. 3, the first isolation layer 201 is formed on a top surface and the sidewall of the bitline structure 15 and the substrate 10 between the bitline structures 15, and the first isolation layer 201 is an inner sidewall of the isolation layer, stuck closely to the sidewall of the bitline structure 15.

The material of the first isolation layer 201 includes silicon nitride, silicon oxynitride, silicon oxide, or the like. In this embodiment, the first isolation layer 201 is made of an insulating material containing nitrogen; that is, the first isolation layer 201 is made of a silicon nitride material. It should be noted that, in this embodiment, the material of the subsequently formed third isolation layer is the same as that of the first isolation layer 201, and in other embodiments, the material of the subsequently formed third isolation layer may be different from that of the first isolation layer.

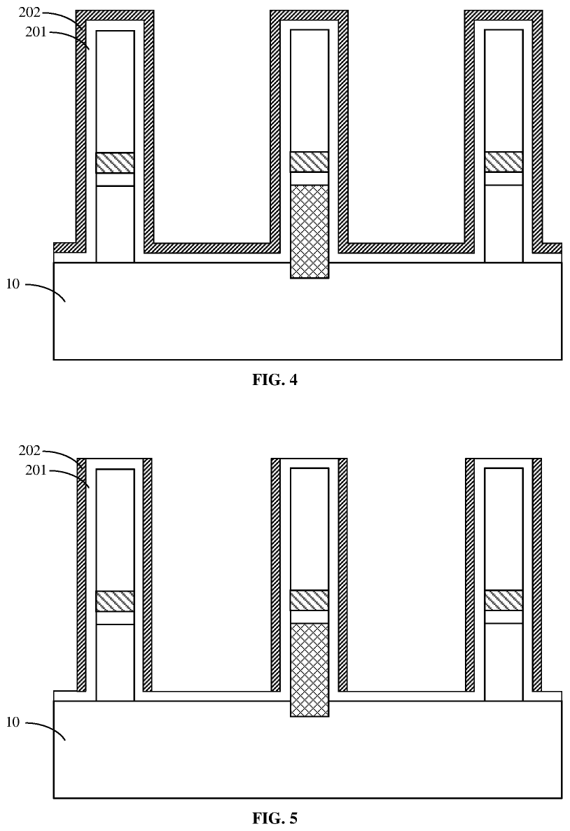

Referring to FIG. 4, the second isolation layer 202 is formed on the top surface and side wall of the first isolation layer 201.

Specifically, the second isolation layer 202 is formed by using atomic layer deposition which has the characteristics of low deposition rate, high compactness of a deposited film layer, good step coverage rate, or the like. Thus, the second isolation layer 202 can be effectively isolated and protected in the case of a small thickness, so as not to occupy a small space between adjacent bitline structures 15, and facilitate the subsequent increase in the sectional area of the bitline contact window.

The material of the second isolation layer 202 includes silicon nitride, silicon oxynitride, silicon oxide, or the like. In the present embodiment, the material of the second isolation layer is an insulating material containing oxygen; that is, the second isolation layer 202 is made of a silicon oxide material. It should be noted that the material of the second isolation layer 202 is different from that of the first isolation layer 201, and is also different from that of the subsequently formed third isolation layer.

Referring to FIG. 5, the second isolation layer 202 on the top surface of the first isolation layer 201 is etched away, and the remaining second isolation layer 202 is located on the side wall of the first isolation layer 201 away from the bitline structure 15.

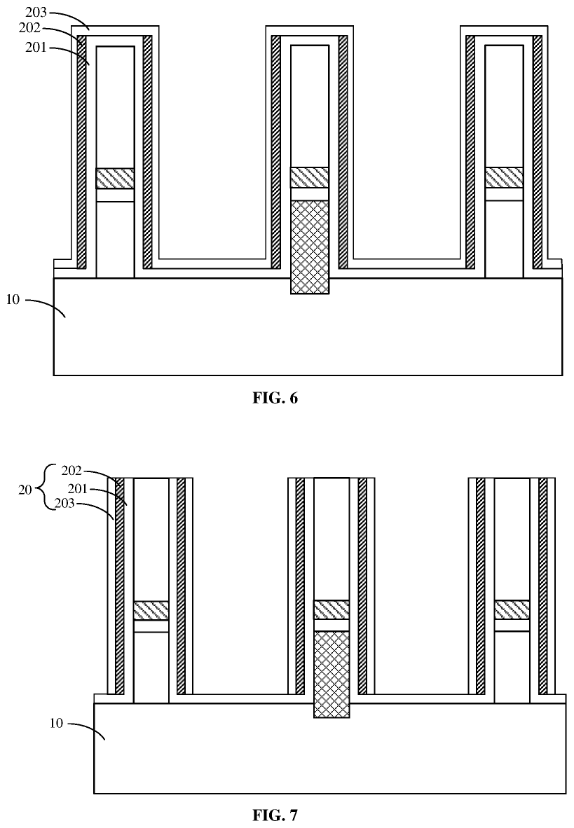

Referring to FIG. 6, the third isolation layer 203 is formed on the top surface of the first isolation layer 201 and the side wall of the second isolation layer 202.

The material of the third isolation layer 203 includes silicon nitride, silicon oxynitride, silicon oxide, or the like. In this embodiment, the third isolation layer 203 is made of an insulating material containing nitrogen; that is, the third isolation layer 203 is made of a silicon nitride material. It should be noted that, in this embodiment, the third isolation layer 203 is made of the same material as the first isolation layer 201 formed as described above.

Referring to FIG. 7, the third isolation layer 203 on the top surface of the first isolation layer 201, and the first isolation layer 201 and the second isolation layer 202 on the top surface of the bitline structure 15 are etched away.

The remaining third isolation layer 203 is located on the side wall of the second isolation layer 202 away from the first isolation layer 201. The first isolation layer 201, the second isolation layer 202 and the third isolation layer 203 stacked on the side wall of the bitline structure 15 in sequence constitute the isolation layer 20.

It should be noted that, in the present embodiment, the NON-laminated isolation layer is used as the isolation layer 20 on the side wall of the bitline structure 15, so as to reduce the parasitic capacitance of the bitline structure 15, without limiting this solution. The thickness of the NON-laminated isolation layer may be flexibly set according to the size of a device in practical application; in addition, other structures may be used as isolation layers on side walls of the bitline structures in other embodiments.

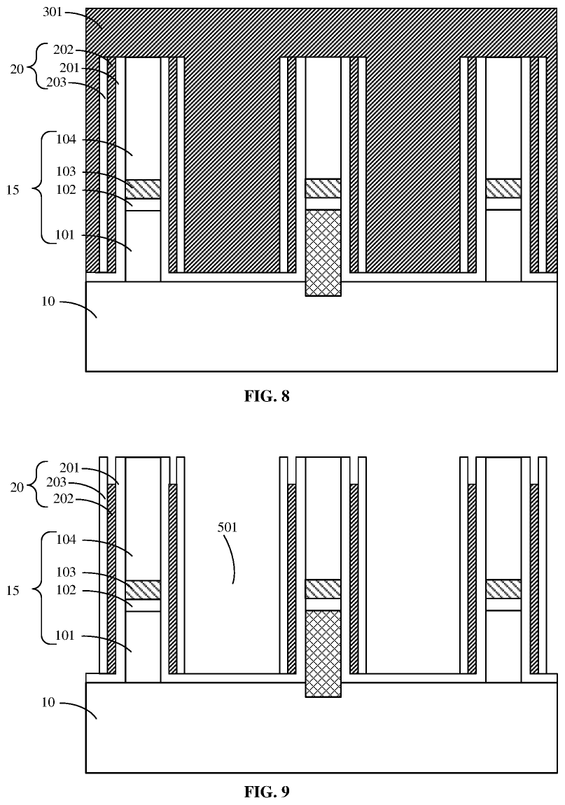

Referring to FIG. 8, a first dielectric layer 301 which covers the bitline structure 15 is formed at the array region and the peripheral region, the material of the first dielectric layer may be the same as or different from that of the second isolation layer 202, and in specific applications, the material may be adjusted according to an etch selectivity ratio of an etching material. In the present embodiment, the material of the first dielectric layer 301 is the same as the material of the second isolation layer 202.

Specifically, a first dielectric film (not shown) filling the gap between the bitline structures 15 is formed at the array region and the peripheral region, and the first dielectric film covers the top surface of the bitline structure 15. The first dielectric film (not shown) is formed by spin coating, with an advantage of good fillibility.

The top surface of the first dielectric film (not shown) is planarized to form the first dielectric layer 301. Specifically, the top surface of the first dielectric film (not shown) is planarized by chemical mechanical polishing with a higher removal rate than etching, which is beneficial to shortening the process cycle.

Referring to FIGS. 8 and 9, the first dielectric layer 301 at the array region is removed to form an opening 501, and during the process of removing the first dielectric layer 301, part of the isolation layer 20 is etched, and the remaining isolation layer 20 has a gap; that is, part of the second isolation layer 202 is etched. Since the NON-laminated isolation structure is formed on the side wall of the bitline structure 15 in this embodiment, the second isolation layer 202 is not etched to a small height.

Specifically, the first dielectric layer 301 at the array region is etched away until the top surface of the bitline structure 15 is exposed; the first dielectric layer 301 between the bitline structures 15 is etched away to form the opening 501. The material for etching away the first dielectric layer 301 includes hydrofluoric acid, which has a high removal rate and is beneficial to shortening the process period.

The removed first dielectric layer 301 still covers the surface of the peripheral region. Since the material of the first dielectric layer 301 is the same as that of the second isolation layer 202, a certain height of the top of the second isolation layer 202 in the isolation layer 20 is etched away to form a gap. In this embodiment, a certain thickness of the second isolation layer 202 is etched.

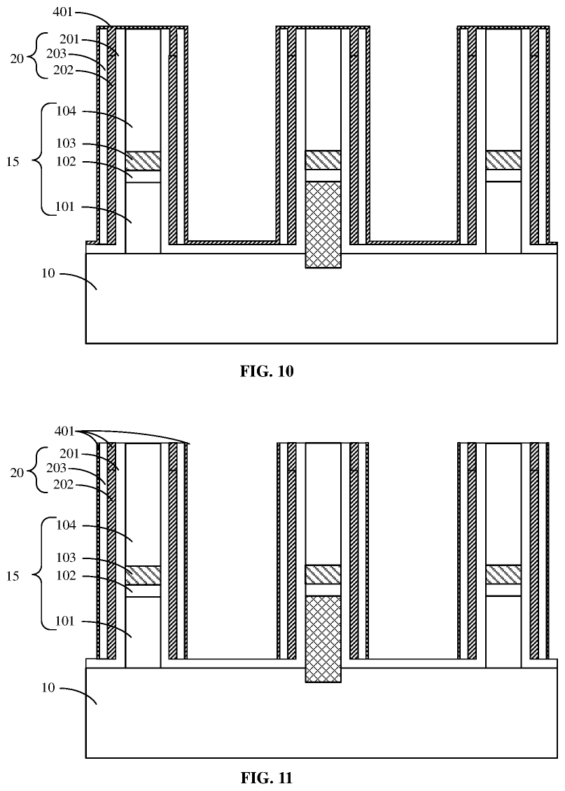

Referring to FIGS. 10 to 12, a second dielectric film 401 is formed on the top surface of the isolation layer 20 and the bitline structure 15, and the second dielectric film 401 is also located on the side wall of the isolation layer 20 and the substrate 10 between the bitline structures 15.

Specifically, a second dielectric film 401 is formed to fill the gap, the second dielectric film 401 being also located on the top surface of the isolation layer 20 and the bitline structure 15.

The second dielectric film 401 filling the gap is formed at the array region, also covering the top surface of the bitline structure 15 and the isolation layer 20, the side wall of the isolation layer 20, and the substrate 10 between the bitline structures.

The second dielectric film 401 on the top surface of the bitline structure 15 and the isolation layer 20 and the substrate 10 between the bitline structures 15 is etched away. In this embodiment, the material of the second dielectric film 401 is the same as that of the first dielectric layer 301.

Specifically, the second dielectric film 401 is formed by using atomic layer deposition which has the characteristics of low deposition rate, high compactness of a deposited film layer, good step coverage rate, or the like. Thus, the gap in the isolation layer 20 may be filled with the second dielectric film 401.

Referring to FIG. 11, the second dielectric film 401 on the side wall of the isolation layer 20 is etched away using the first etching process to form the second dielectric layer 402.

Since the isolation structure on the side wall of the bitline structure 15 is a NON-laminated isolation structure in this embodiment, the isolation effect is good, and the second dielectric layer 402 on an outer layer of the isolation layer 20 will decrease the sectional area of the bitline contact window formed subsequently. Thus, the second dielectric layer 402 on the side wall of the isolation layer 20 is etched away using the first etching process.

Specifically, the first etching process is isotropic etching, with etching gas being mixed gas of CF₄, CHF₃, and O₂, wherein CF₄ has a gas flow ranging from 100 sccm to 300 sccm, CHF₃ has a gas flow ranging from 50 sccm to 200 sccm, and O₂ has a gas flow ranging from 1 sccm to 20 sccm; an etching pressure ranges from 5 mtor to 16 mtor; an etching power ranges from 200 W to 600 W; an etching voltage is 0V; an etching temperature ranges 20° C. to 80° C.; etching lasts for 5 s to 30 s, and by appropriately controlling the time of the first etching process, the second dielectric layer 402 may be completely etched on the side wall of the isolation layer 20, or the second dielectric layer 402 with a certain thickness may be etched on the side wall of the isolation layer 20, thereby increasing the sectional area of the opening between the bitline structures 15, namely, the sectional area of the capacitor contact window formed subsequently, so as to reduce the resistance of the capacitor contact window formed subsequently.

In this embodiment, the parameter range of the first etching process is as follows. The mixed gas of CF₄ with a gas flow of 180 sccm to 220 sccm, CHF₃ with a gas flow of 100 sccm-150 sccm and O₂ with a gas flow of 5 sccm to 10 sccm is taken as the etching gas, the etching pressure ranges from 7 mtor to 12 mtor, the etching power ranges from 350 W to 450 W; the etching voltage is 0V; the etching temperature is 60° C., and the etching lasts for 15 s to 20 s.

Referring to FIG. 12, a second etching process is used to etch part of the substrate 10 at the bottom of the opening 501 to form a capacitor contact hole 502.

In the second etching process, the etch selectivity ratio is different for the first isolation layer 201, polysilicon in the substrate 10 and an oxide layer in the substrate 10. Namely, the etching rate to the first isolation layer 201 (nitride) is the highest, the etching rate to the polysilicon in the substrate 10 is the lowest, and the etching rate to the oxide layer (oxide) in the substrate 10 is moderate.

Specifically, the second etching process is first used to etch away the first isolation layer 201 at the bottom of the opening 501, and then, continuously used to etch part of the substrate 10 at the bottom of the opening 501 to form the capacitor contact hole 502.

Since the etching rate to the first isolation layer 201 is the highest in the second etching process, the first isolation layer 201 can be etched quickly, which shortens the etching time, and avoids the influence on the subsequent process procedure due to an overly large height difference between the array region and the peripheral region since a great thickness of the top of the bitline structure 15 is etched.

Since the etching rate to the polysilicon in the substrate 10 is relatively low in the second etching process, more polysilicon in the substrate 10 is prevented from being etched away, thereby avoiding the problem of electrical failure of the DRAM. The etching rates to the polysilicon and the oxide layer in the substrate 10 by the second etching process are different, so that the bottom of the etched capacitor contact hole 502 is not a flat surface, and the contact area between the subsequently formed capacitor contact window and the substrate 10 is increased relative to the flat surface, thereby reducing the resistance of the subsequently formed capacitor contact window and being beneficial to increasing the saturation current of the DRAM array region. In other embodiments, the material of the second etching process is selected so long as the oxide layer and the polysilicon in the substrate have a greater etch selectivity ratio.

Specifically, in the second etching process, the etching gas is the mixed gas of CF₄, CHF₃, and He, wherein CF₄ has a gas flow ranging from 30 sccm to 70 sccm, He has a gas flow ranging from 50 sccm to 150 sccm; an etching pressure ranges from 5 mtor to 16 mtor; an etching power ranges from 300 W to 700 W; an etching voltage ranges 100V to 400V; an etching temperature ranges 20° C. to 80° C.

In this embodiment, the parameter range of the second etching process is as follows. The mixed gas of CF₄ with a gas flow of 45 sccm to 55 sccm, and He with a gas flow of 100 sccm is taken as the etching gas, the etching pressure ranges from 7 mtor to 12 mtor, the etching power ranges from 450 W to 550 W; the etching voltage ranges 200V to 300V; the etching temperature is 60° C.

Compared with a related art, in the present application, the parasitic capacitance of the DRAM array region is reduced by forming an isolation structure, which leads to a gap formed between the top of the isolation layer 20 and the bitline structure 15 in the subsequent process, and an isolation effect of the isolation structure is guaranteed by forming the second dielectric layer 402 to fill a gap; and with the first etching process and the second etching process, the second dielectric layer 402 on the side wall of the isolation layer 20 and the substrate 10 at the bottom of part of the opening 501 are etched, which increases the contact area of the capacitor contact hole, thereby reducing the resistance of the subsequently formed capacitor contact window and increasing the saturation current of the DRAM array region.

The above steps are divided for clarity of description, and may be combined into one step or split into multiple steps during implementation. All steps, divided or combined, shall fall within the scope of protection of the present patent so long as they include the same logical relationship; inessential amendments added in a flow or inessential designs introduced in the flow, and the key design not changing its flow shall fall within the scope of protection of the present patent.

Another embodiment of the present application relates to a method for forming a memory, which is different from the above embodiments in that an isolation structure finally formed in the present embodiment is an air isolation structure, and the method specifically includes the following steps.

The third isolation layer on the top surface of the first isolation layer, and the first isolation layer and the third isolation layer on the top surface of the bitline structure are etched away.

The remaining third isolation layer is located on the side wall of the second isolation layer away from the first isolation layer. The first isolation layer, the second isolation layer and the third isolation layer which are sequentially stacked on the side wall of the bitline structure form the isolation layer.

It should be noted that, in the present embodiment, the air gap isolation structure is used as the isolation structure of the side wall of the bitline structure; that is, the second isolation layer is required to be removed in the subsequent process to form the air gap. The air gap is used as the isolation structure, so as to reduce the parasitic capacitance of the bitline structure.

The first dielectric layer which covers the bitline structure is formed at the array region and the peripheral region.

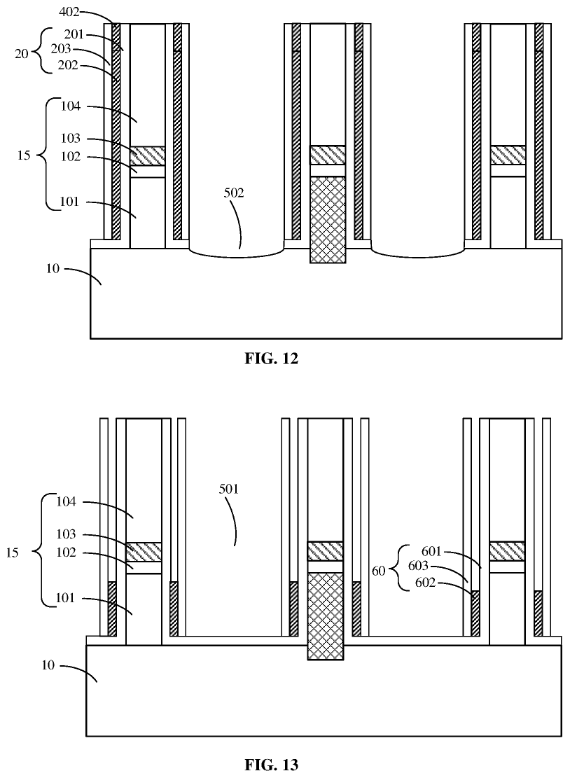

FIGS. 13 to 16 are schematic structural diagrams corresponding to steps of a method for forming a memory according to the present embodiment, and the details of the present embodiment will be specifically described below in combination with the drawings. The contents the same as the above-mentioned embodiments are omitted herein.

Referring to FIG. 13, the first dielectric layer at the array region is removed to form the opening 501, and during the process of removing the first dielectric layer, part of the isolation layer 60 is etched, and a gap exists between the remaining isolation layer 60 and the bitline structure 15. That is, part of the second isolation layer 602 is etched. A great height of the second isolation layer 602 is etched since the air gap is required to be formed in this embodiment.

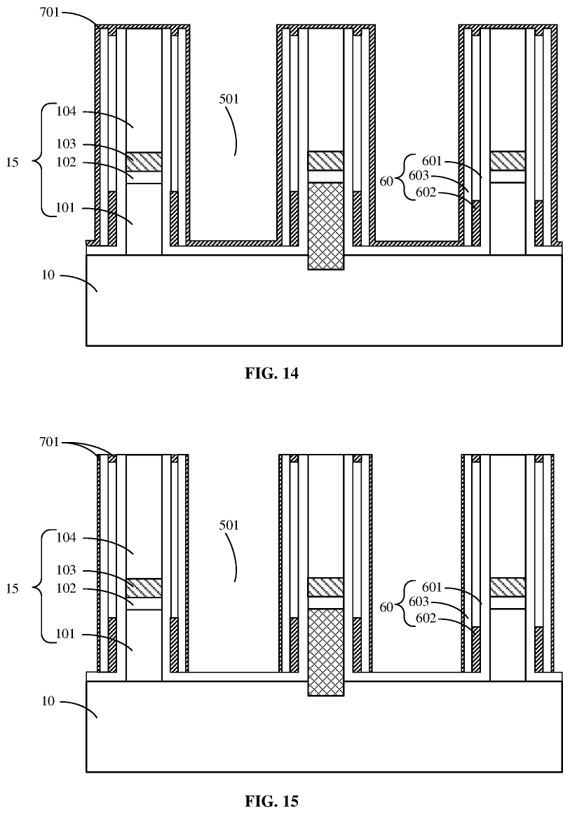

Referring to FIG. 14, a second dielectric film 701 is formed on the top surface of the isolation layer 60 and the bitline structure 15, the second dielectric film 701 being also on the substrate 10 between the side wall of the isolation layer 60 and the bitline structure 15.

Specifically, the second dielectric film 701 is formed to seal the gap, part of the second dielectric film 701 is located on top of the gap, and the second dielectric film 701 is also located on the top surface of the isolation layer 60 and the bitline structure 15.

The second dielectric film 701 is formed on the top surface of the isolation layer 60 and the bitline structure 15 by using a quick sealing process, and the second dielectric film 701 also covers the side wall of the isolation layer 60 and the substrate 10 between the bitline structures 15.

The second dielectric film 701 on the top surface of the isolation layer 60 and the bitline structure 15 and on the substrate 10 between the bitline structure 15 is etched away. It should be noted that, in this embodiment, the material of the second dielectric film 701 is the same as that of the first dielectric layer, but in other embodiments, the material of the second dielectric film may be different from that of the first dielectric layer.

Specifically, the second dielectric film 701 is formed by the quick sealing process, which has an effect of rapid deposition, and the formed second dielectric film 701 is configured to seal the top of the isolation layer 60 to form the air isolation structure.

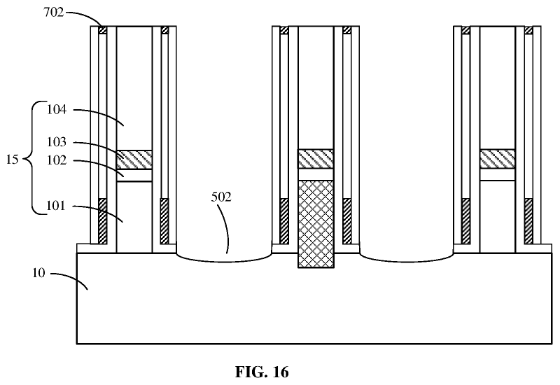

Referring to FIGS. 15 and 16, the second dielectric film 701 on the side wall of the isolation layer 60 is etched away using the first etching process to form a second dielectric layer 702.

Since in the present embodiment, the isolation structure located on the side wall of the bitline structure 15 is an air gap isolation structure, with good isolation effects and the second dielectric film 701 outside the isolation layer 60 will lead to the decreased sectional area of the subsequently formed bitline contact window. Therefore, the second dielectric film 701 on the side wall of the isolation layer 60 is etched away by the first etching process.

By appropriately controlling the time of the first etching process, the second dielectric film 701 may be completely etched on the side wall of the isolation layer 60, or the second dielectric film 701 with a certain thickness may be etched on the side wall of the isolation layer 60, thereby increasing the sectional area of the opening 501 between the bitline structures 15, namely, the sectional area of the capacitor contact window formed subsequently, so as to reduce the resistance of the capacitor contact window formed subsequently. The remaining second dielectric film 701 after etch forms the second dielectric layer 702 which is located on top of the gap in the isolation layer 60, so that the isolation layer 60 forms the air gap isolation structure.

Referring to FIG. 16, the second etching process is performed to etch part of the substrate 10 at the bottom of the opening 501 to form the capacitor contact hole 502.

In the second etching process, the etch selectivity ratio is different for the first isolation layer 201, polysilicon in the substrate 10 and an oxide layer in the substrate 10. Namely, the etching rate to the first isolation layer 201 (nitride) is the highest, the etching rate to the polysilicon in the substrate 10 is the lowest, and the etching rate to the oxide layer (oxide) in the substrate 10 is moderate.

Specifically, the second etching process is first used to etch away the first isolation layer 201 at the bottom of the opening 501, and then, continuously used to etch part of the substrate 10 at the bottom of the opening 501 to form the capacitor contact hole 502.

Compared with the related art, in the present application, the parasitic capacitance of the DRAM array region is reduced by forming an isolation structure, which leads to a gap formed between the top of the isolation layer 60 and the bitline structure 15 in the subsequent process, and the isolation layer 60 is sealed by forming the second dielectric layer 702, guaranteeing the formation of the air gap isolation structure; and with the first etching process and the second etching process, the second dielectric film 701 on the side wall of the isolation layer 60 and the substrate 10 at the bottom of part of the opening 501 are etched, which increases the contact area of the capacitor contact hole, thereby reducing the resistance of the subsequently formed capacitor contact window and increasing the saturation current of the DRAM array region.

The above steps are divided for clarity of description, and may be combined into one step or split into multiple steps during implementation. All steps, divided or combined, shall fall within the scope of protection of the present patent so long as they include the same logical relationship; inessential amendments added in a flow or inessential designs introduced in the flow, and the key design not changing its flow shall fall within the scope of protection of the present patent.

It should be noted that, in the above embodiment, the method for increasing the contact area of the subsequently formed capacitor contact window through the first etching process and the second etching process in the present application is introduced by using the NON-laminated isolation structure and the air isolation structure respectively, without limiting the applications of the first etching process and the second etching process in the present application. Those skilled in the art know that the embodiment of increasing the contact area of the subsequently formed capacitor contact window through the above etching process may also be applied to DRAM array region structures of other isolation structures.

Another embodiment of the present application relates to a memory, which can be formed by the above forming method, the memory according to the present embodiment will be described in detail below with reference to the accompanying drawings, and the same or corresponding portions as or to those in the above embodiments will not be described in detail below.

Referring to FIG. 12, a memory includes: a substrate 10, the substrate 10 including an array region and a peripheral region, the array region having thereon a plurality of discrete bitline structures 15; an isolation layer 20 located on a side wall of the bitline structure 15 and having a gap; a first dielectric layer which covers the peripheral region and a second dielectric layer 402 located in the gap, for forming an isolation structure; the substrate 10 between the bitline structures 15 having thereon a capacitor contact hole 502.

In the present embodiment, the second dielectric layer 402 is configured to fill the gap to form the isolation structure.

The substrate 10 includes buried wordlines, shallow trench isolation layers, active regions, or the like. The bitline structure 15 includes a bitline contact layer 101, a bottom dielectric layer 102, a metal layer 103, and a top dielectric layer 104. Specifically, the bitline contact layer 101 includes the bitline contact window 13. A material of the bitline contact window 13 includes tungsten or polysilicon, materials of the bottom dielectric layer 102 and the top dielectric layer 104 include silicon nitride, silicon dioxide or silicon oxynitride, and the metal layer 103 is made of a conductive material or a plurality of conductive materials, such as doped polysilicon, titanium, titanium nitride, tungsten, tungsten compounds, or the like.

The isolation layer 20 includes a first isolation layer 201, a second isolation layer 202 and a third isolation layer 203; the first isolation layer 201 is located on aside wall of the bitline structure 15; the second isolation layer 202 is located on the sidewall of the first isolation layer 201 away from the bitline structure 15; the material of the second isolation layer 202 is the same as that of the first dielectric layer; the third isolation layer 203 is located on the side wall of the second isolation layer 202 away from the first isolation layer 201.

The material of the first isolation layer 201 includes silicon nitride, silicon oxynitride, silicon oxide, silicon oxide, or the like. In this embodiment, the first isolation layer 201 is made of an insulating material containing nitrogen; that is, the first isolation layer 201 is made of a silicon nitride material. The material of the second isolation layer 202 includes silicon nitride, silicon oxynitride, silicon oxide, silicon oxide, or the like. In this embodiment, the second isolation layer 202 is made of a silicon oxide material. The material of the third isolation layer 203 includes silicon nitride, silicon oxynitride, silicon oxide, silicon oxide, or the like. In this embodiment, the third isolation layer 203 is made of an insulating material containing nitrogen; that is, the third isolation layer 203 is made of a silicon nitride material.

It should be noted that the third isolation layer 203 is made of the same material as the first isolation layer 201, and the second isolation layer 202 is made of a material different from the first isolation layer 201 and the third isolation layer 203.

In the present embodiment, the material of the first dielectric layer 301 is the same as the material of the second isolation layer 202, and the material of the second dielectric layer 402 is the same as the material of the first dielectric layer 301.

In other embodiments, referring to FIG. 16, a memory includes: a substrate 10, the substrate 10 including an array region and a peripheral region, the array region having thereon a plurality of discrete bitline structures 15; an isolation layer 60 located on a side wall of the bitline structure 15 and having a gap; a first dielectric layer which covers the peripheral region and a second dielectric layer 702 located in the gap, for forming an isolation structure; the substrate 10 between the bitline structures 15 having thereon a capacitor contact hole 502.

At this point, the second dielectric layer 702 is configured to seal the gap to form the isolation structure.

Compared with the related art, in the present application, the parasitic capacitance of the bitline structure is reduced by the isolation structure, the contact area between the subsequently formed capacitor contact window and the substrate 10 is increased and the resistance of the subsequently formed capacitor contact window is decreased through the capacitor contact hole formed by etching on the substrate 10 between the bitline structures 15, thereby increasing the saturation current of the DRAM array region.

The above embodiment and the present embodiment may be coordinately implemented due to their correspondence. The details of the related art mentioned in the above embodiment are applicable in the present embodiment, and the technical effects achievable in the above embodiment can also be realized in the present embodiment, which are not described here to reduce repetition. Correspondingly, the details of the related art mentioned in the present embodiment are also applicable in the above embodiment.

Those skilled in the art understand that the above embodiments are implementations of the present application. However, in practical applications, various changes may be made to them in view of form and detail without departing the spirit and range of the present application.

What is claimed is:

1. A method for forming a memory, comprising:
providing a substrate, the substrate comprising an array region and a peripheral region, the array region having thereon a plurality of discrete bitline structures, and the bitline structure being provided with an isolation layer on a side wall;
forming a first dielectric layer which covers the bitline structure at the array region and the peripheral region;
patterning and etching the first dielectric layer located at the array region to form an opening, and etching part of the isolation layer during a process of etching away the first dielectric layer, a remaining part of the isolation layer having a gap;
forming a second dielectric film located on a top surface of the isolation layer and the bitline structure, the second dielectric film being also located on aside wall of the isolation layer and the substrate between the bitline structures;
by a first etching process, etching the second dielectric film on the side wall of the isolation layer to form a second dielectric layer; and
by a second etching process, etching part of the substrate at a bottom of the opening to form a capacitor contact hole.

2. The method for forming a memory according to claim 1, wherein the forming a second dielectric film located on a top surface of the isolation layer and the bitline structure comprises: forming the second dielectric film for filling the gap, the second dielectric film being also located on the top surface of the isolation layer and the bitline structure.

3. The method for forming a memory according to claim 1, wherein the forming a second dielectric film located on a top surface of the isolation layer and the bitline structure comprises: forming the second dielectric film for sealing the gap, the second dielectric film being partially located on top of the gap, the second dielectric film being also located on the top surface of the isolation layer and the bitline structure.

4. The method for forming a memory according to claim 2, wherein after the forming a second dielectric film located on a top surface of the isolation layer and the bitline structure and before the etching the second dielectric film on the side wall of the isolation layer by the first etching process, the method comprises: etching away the second dielectric film on the top surface of the isolation layer and the bitline structure and on the substrate between the bitline structures.

5. The method for forming a memory according to claim 1, wherein the etching the first dielectric layer located at the array region to form an opening comprises:
etching away the first dielectric layer located at the array region until atop surface of the bitline structure is exposed; and
etching away the first dielectric layer located between the bitline structures to form the opening.

6. The method for forming a memory according to claim 1, wherein:
the isolation layer comprises a first isolation layer, a second isolation layer and a third isolation layer;
the first isolation layer is located on the side wall of the bitline structure;
the second isolation layer is located on aside wall of the first isolation layer away from the bitline structure;
the third isolation layer is located on aside wall of the second isolation layer away from the second isolation layer; and
the etching part of the isolation layer during a process of etching away the first dielectric layer comprises: etching part of the second isolation layer with a certain thickness.

7. The method for forming a memory according to claim 6, wherein the forming a first dielectric layer which covers the bitline structure at the array region and the peripheral region comprises:
forming a first dielectric film for filling a gap between the bitline structures at the array region and the peripheral region, the first dielectric film covering a top surface of the bitline structure; and
planarizing a top surface of the first dielectric film to form the first dielectric layer.

8. A memory, comprising:
a substrate, the substrate comprising an array region and a peripheral region, the array region having thereon a plurality of discrete bitline structures;
an isolation layer located on a side wall of the bitline structure, the isolation layer having a gap;
a first dielectric layer which covers the peripheral region and a second dielectric layer located in the gap for forming an isolation structure; and
a capacitor contact hole on the substrate between the bitline structures.

9. The memory according to claim 8, wherein the second dielectric layer is configured to fill the gap to form the isolation structure, or the second dielectric layer is configured to seal the gap to form the isolation structure.

10. The memory according to claim 8, wherein:
the isolation layer comprises a first isolation layer, a second isolation layer and a third isolation layer;
the first isolation layer is located on the side wall of the bitline structure;
the second isolation layer is located on aside wall of the first isolation layer away from the bitline structure; and
the third isolation layer being located on aside wall of the second isolation layer away from the second isolation layer.

11. The method for forming a memory according to claim 3, wherein after the forming a second dielectric film located on a top surface of the isolation layer and the bitline structure and before the etching the second dielectric film on the side wall of the isolation layer by the first etching process, the method comprises: etching away the second dielectric film on the top surface of the isolation layer and the bitline structure and on the substrate between the bitline structures.
